(19) United States
(12) Patent Application Publication
(10) Pub. No.: US 2026/0056380 A1
(43) Pub. Date: Feb. 26, 2026

(54) PHOTONIC CHIP INCLUDING ELECTRICAL INTERCONNECTIONS WITH A DUAL-LOBED PILLAR

(71) Applicant: GlobalFoundries U.S. Inc., Malta, NY (US)

(72) Inventors: Kashi Vishwanath Machani, Dresden (DE); Scott Pozder, Saratoga Springs, NY (US); Yunyao Jiang, Mechanicville, NY (US); Frank Küchenmeister, Dresden (DE); Willie James Yarbrough, Dallas, TX (US); Jae Kyu Cho, Niskayuna, NY (US)

(21) Appl. No.: 18/813,167

(22) Filed: Aug. 23, 2024

(51) Int. Cl. G02B 6/42; H01L 23/00; H01L 25/16

(52) U.S. Cl. CPC G02B 6/4283; H01L 24/16; H01L 24/32; H01L 24/73; H01L 25/167; H01L 2224/16225; H01L 2224/32225; H01L 2224/73204; H01L 2924/351

(57) ABSTRACT

Structures for a photonic chip and associated methods. The structure comprises a photonic chip including a bond pad and forming an electrical interconnection that includes a pillar positioned on the bond pad. The pillar includes a first lobed section, a second lobed section spaced from the first lobed section by a gap, and a connecting section extending across a portion of the gap to connect the first lobed section to the second lobed section.

### BACKGROUND

The present disclosure relates generally to semiconductor devices and integrated circuit fabrication and, more specifically, to structures for a photonic chip and associated methods.

Photonic chips are used in many applications and systems including, but not limited to, data communication systems and data computation systems. A photonic chip includes a photonic integrated circuit comprised of photonic components, such as modulators, polarizers, and optical couplers, that are used to manipulate light received from a light source, such as an optical fiber or a laser.

A photonic chip may be mounted on a laminate substrate to create a package assembly. Copper pillars or bumps may provide electrical interconnections between the laminate substrate and photonic chip. However, the copper bumps may cause failures in underlying portions of the back-end-of-line stack of the photonic chip due to strain transferred from stressed copper bumps to the interlayer dielectric layers of the back-end-of-line stack.

Improved structures for a photonic chip, and associated methods, are needed.

### SUMMARY

In an embodiment, a structure comprises a photonic chip including a bond pad and forming an electrical interconnection that includes a pillar positioned on the bond pad. The pillar includes a first lobed section, a second lobed section spaced from the first lobed section by a gap, and a connecting section extending across a portion of the gap to connect the first lobed section to the second lobed section.

In an embodiment, a method comprises forming a photonic chip including a bond pad and forming an electrical interconnection that includes a pillar positioned on the bond pad. The pillar includes a first lobed section, a second lobed section spaced from the first lobed section by a gap, and a connecting section extending across a portion of the gap to connect the first lobed section to the second lobed section.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals are used to indicate like features in the various views.

FIG. 1 is a cross-sectional view of a package assembly in accordance with an embodiment of the invention.

FIG. 2 is an enlarged view of a portion of FIG. 1.

FIG. 3 is a top view of a portion of an electrical interconnection between the photonic chip and the laminate substrate of the package assembly of FIG. 1 before attachment of the laminate substrate to the photonic chip.

FIG. 4 is a cross-sectional view taken generally along line 4-4 in FIG. 3.

FIG. 5 is a top view of an electrical interconnection between the photonic chip and the laminate substrate of the package assembly in accordance with an alternative embodiment of the invention.

FIG. 5A is a cross-sectional view taken generally along line 5A-5A in FIG. 5.

FIG. 6 is a top view of an electrical interconnection between the photonic chip and the laminate substrate of the package assembly in accordance with an alternative embodiment of the invention.

FIG. 7 is a cross-sectional view of an electrical interconnection between the photonic chip and the laminate substrate of the package assembly in accordance with an alternative embodiment of the invention.

FIG. 8 is a cross-sectional view of an electrical interconnection between the photonic chip and the laminate substrate of the package assembly in accordance with an alternative embodiment of the invention.

### DETAILED DESCRIPTION

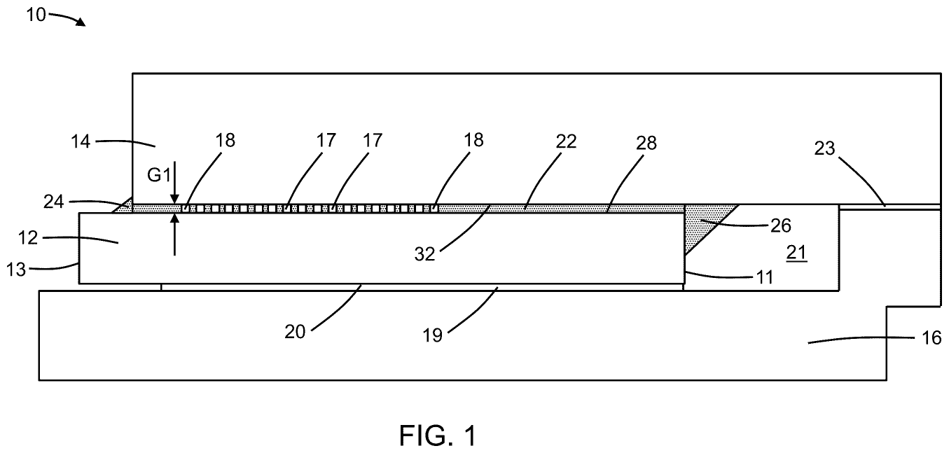

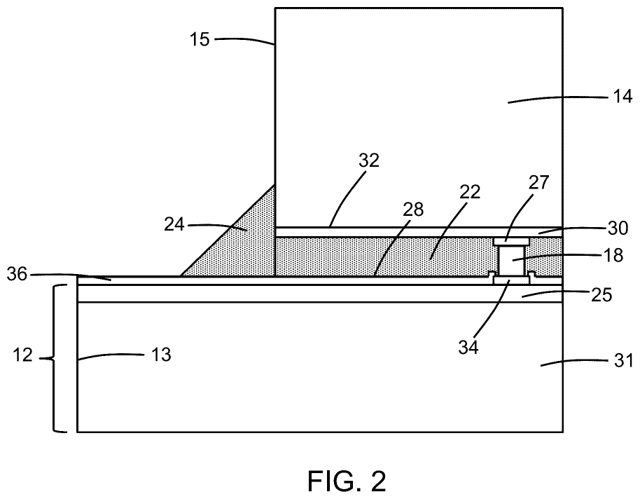

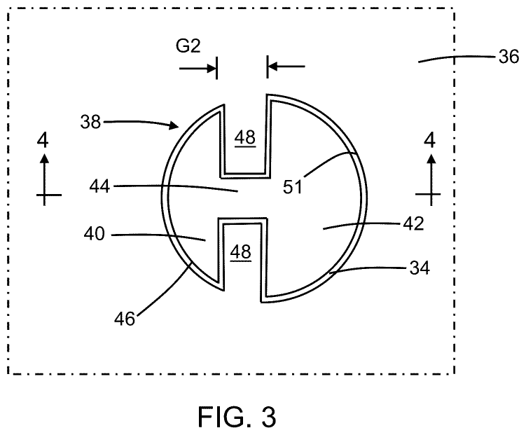

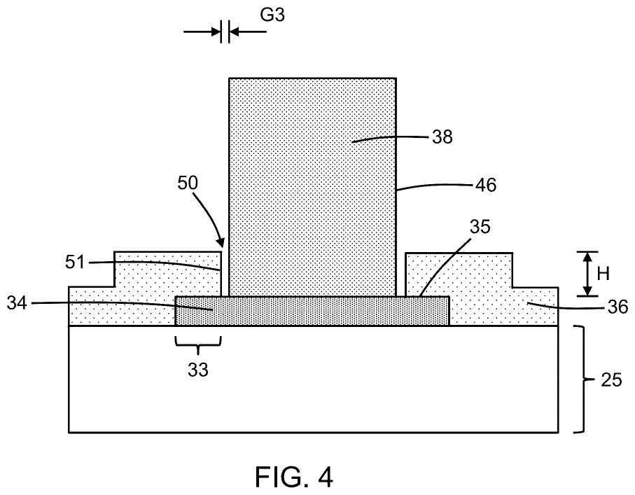

With reference to FIGS. 1, 2, 3, 4 and in accordance with embodiments of the invention, a structure 10 for a lidded package assembly includes a photonic chip 12, a laminate substrate 14 that provides a representative packaging substrate, and a lid 16. The photonic chip 12 is disposed between the laminate substrate 14 and the lid 16. The laminate substrate 14 may include an epoxy-glass cloth core and alternating layers of metal and electrical insulator that are laminated to the core. In an embodiment, the laminate substrate 14 may include layers of a copper film that alternative with layers of an insulating resin, such as Ajinomoto Build-up Film (ABF). A build-up of the alternating layers of the laminate substrate 14 may be disposed adjacent to the photonic chip 12.

The photonic chip 12 includes photonic components, such as modulators, polarizers, and optical couplers, arranged in a functional photonic integrated circuit that is configured to manipulate light received from a light source, such as an optical fiber or a laser. The photonic chip 12 includes a substrate 31 on which the photonic integrated circuit is disposed and a back-end-of-line stack 25 disposed on the substrate 31. The substrate 31 may be comprised of, for example, silicon. The back-end-of-line stack 25, which may include bond pads 34, a set of interlayer dielectric layers, and interconnects in the interlayer dielectric layers, may be disposed adjacent to the laminate substrate 14. Each interlayer dielectric layer may be comprised of a dielectric material, such as a low-k dielectric material, silicon nitride, or silicon dioxide, and the interconnects may be comprised of a metal, such as aluminum or copper.

A dielectric layer 36 comprised of an inorganic dielectric material, such as silicon dioxide formed using tetraethyl orthosilicate, may be formed as a passivation layer on the surface of the back-end-of-line stack 25 at which the bond pads 34 are exposed. In an embodiment, the dielectric layer 36 may have a thickness on the order of six (6) micrometers. The inorganic dielectric material constituting the dielectric layer 36 may be characterized by a high stiffness and a low coefficient of thermal expansion, particular in comparison to an organic material such as polyimide.

The laminate substrate 14 includes bond pads 27 that are coupled by vias to the metal layers in the build-up. A surface 32 of the laminate substrate 14, which is adjacent to a top surface 28 of the back-end-of-line stack 25 of the photonic chip 12, may be coated by a solder mask layer 30 that is coterminous with an edge 15 of the laminate substrate 14. Electrical interconnections 17, 18 couple the bond pads 34 of the photonic chip 12 to the bond pads 27 of the laminate substrate 14. The electrical interconnections 17, 18 are arranged in a gap G1 between the top surface 28 of the back-end-of-line stack 25 and the surface 32 of the laminate substrate 14. One of the electrical interconnections 18 may be located adjacent to the entrance to the gap G1 nearest to the side surface 13 of the photonic chip 12. The other of the electrical interconnections 18 may be located adjacent to the entrance to the gap G1 nearest the side surface 11 of the photonic chip 12. All of the electrical interconnections 17 may be arranged between the electrical interconnections 18 that are located at the entrances at the opposite sides of the gap G1.

The photonic chip 12 also includes a bottom surface 20 that is opposite to the top surface 28, a side surface 11, and a side surface 13 that is opposite to the side surface 11. The side surfaces 11, 13 are connected by the bottom surface 20 and the top surface 28. The photonic chip 12 includes a portion that is disposed between the side surface 13 and the edge 15 of the laminate substrate 14 due to a lateral offset in the attachment of the photonic chip 12 to the laminate substrate 14. The side surface 11 is overlapped by the laminate substrate 14, and the side surface 13 is not overlapped by the laminate substrate 14.

The lid 16, which may be comprised of an electrically-conductive and thermally-conductive material, such as nickel-coated copper, is attached to same side of the laminate substrate 14 as the photonic chip 12. The photonic chip 12 overlaps with a portion of the lid 16. A layer 19 of thermal interface material may be disposed between the photonic chip 12 and the overlapped portion of the lid 16. The thermal interface material in the layer 19 may be comprised of, for example, a thermal adhesive or a thermal grease that functions to improve heat flow between the photonic chip 12 and the overlapped portion of the lid 16.

Another portion of the lid 16 may be attached to a portion of the surface 32 of the laminate substrate 14 by an adhesive layer 23. An open space 21 is disposed between the side surface 11 of the photonic chip 12, the lid 16, and a portion of the surface 32 of the laminate substrate 14. The different portions of the lid 16 are characterized by a vertical offset that accommodates the placement of the photonic chip 12 between the laminate substrate 14 and the lid 16. The attachment of the portion of the lid 16 to the laminate substrate 14 adds mechanical strength to the structure 10 and, if the adhesive constituting the adhesive layer 23 is conductive, may provide a conductive path from the lid 16 to the laminate substrate 14.

A layer 22 comprised of an underfill material may be disposed in the gap G1 between the photonic chip 12 and the laminate substrate 14 that includes the electrical interconnections 17, 18. The layer 22 may have a thickness that is substantially equal to the height dimension of the gap G1. The layer 22 protects the electrical interconnections 17, 18 against various adverse environmental factors, redistributes mechanical stresses due to shock, and prevents the electrical interconnections 17, 18 from moving under strain during thermal cycles when the photonic chip 12 is operating.

A fillet 24 comprised of an underfill material is disposed on a portion of the top surface 28 of the photonic chip 12 adjacent to the edge 15 of the laminate substrate 14 and adjacent to the gap G1. A fillet 26 comprised of an underfill material is disposed on a portion of the side surface 11 of the photonic chip 12 adjacent to the surface 32 of the laminate substrate 14 and adjacent to the gap G1.

Each electrical interconnection 18 may include a pillar 38 that is positioned on one of the bond pads 34 of the photonic chip 12. In an embodiment, the pillar 38 may be positioned directly on a central portion of a top surface 35 of the bond pad 34. In an embodiment, the top surface 35 of the bond pad 34 may be planar. The pillar 38 may be comprised of a metal, such as copper, and may be capped by one or more capping layers comprised of solder or a barrier layer comprised of nickel or another metal. The pillar 38 may be formed by a plating process.

The pillar 38 may have a dual-lobed shape, from a vertical perspective, that includes a lobed section 40, a lobed section 42 spaced from the lobed section 40 by a gap G2, a connecting section 44 that connects a portion of the lobed section 40 to a portion of the lobed section 42, and an outer sidewall 46 that traces the outer boundary of the lobed sections 40, 42 and the connecting section 44. In an embodiment, the lobed section 40 includes a curved edge as a portion of the outer sidewall 46, the lobed section 42 includes a curved edge as a portion of the outer sidewall 46, and the connecting section 44 is connected to a portion of the lobed section 42 and a portion of the lobed section 40 that face each other across the gap G2.

The connecting section 44 provides a bridge that extends across the gap G2 between the lobed section 40 and the lobed section 42. The pillar 38 includes notches 48 in its outer sidewall 46 that may extend over the full height of the pillar 38 to the underlying bond pad 34. The notches 48, which are disposed between the lobed section 40 and the lobed section 42, represent portions of the gap G2 that are separated from each other by the connecting section 44. The connecting section 44 is laterally positioned between the notches 48.

The lobed section 40 and the lobed section 42 may have different sizes such that the pillar 38 is asymmetric. In an embodiment, the lobed section 40 may be smaller than the lobed section 42. In an embodiment, the pillar 38 may be rotationally oriented such that the lobed section 40 is closer to the side surface 13 of the photonic chip 12 than the lobed section 42 or closer to the side surface 11 of the photonic chip 12 than the lobed section 42.

The dielectric layer 36 includes an opening 50 with a sidewall 51 that surrounds the pillar 38. The dielectric layer 36 overlaps with a portion 33 of the bond pad 34 that is adjacent to the sidewall 51 of the opening 50. The opening 50 may have a dual-lobed shape that matches the dual-lobed shape of the dual-lobed pillar 38 and that is slightly larger than the dual-lobed shape of the dual-lobed pillar 38 such that a gap G3 exists between the outer sidewall 46 of the pillar 38 and the sidewall 51 of the opening 50 in the dielectric layer 36. More specifically, an inner perimeter of the outer sidewall 46 may trace the outer sidewall 46 dual-lobed pillar 38 with an open space therebetween defining the gap G3, the opening 50 may have a lobed section along its inner perimeter that coincides in location with the lobed section 40, and the opening 50 may have a lobed section along its inner perimeter that coincides in location with the lobed section 42. The gap G3 extends downwardly between the sidewall 51 of the opening 50 and the outer sidewall 46 of the pillar 38 over the height H of the opening 50 to the top surface 35 of the bond pad 34 such that the dielectric layer 36 has a non-contacting and spaced-apart relationship with the pillar 38. In an embodiment, the opening 50 may have a section along its sidewall 51 that coincides in location with the connecting section 44 along the outer sidewall 46 of the pillar 38. In an embodiment, the sidewall 51 of the opening 50 may be oriented perpendicular to a horizontal plane established by the top surface 35 of the bond pad 34 such that the opening 50 is a right circular cylinder. In an embodiment, the gap G3 may have an average width dimension that is constant over the height H of the pillar 38. In an embodiment, the average width dimension of the gap G3 may be selected to optimize the associated benefit by reducing the strain transferred from the pillar 38 to the interlayer dielectric layers of the back-end-of-line stack 25. In an embodiment, the average width dimension of the gap G3 may be less than about 1 micrometer.

The dual-lobed shape of the pillar 38 and the shape of the opening 50, which may also be dual lobed, in the dielectric layer 36 may cooperate to significantly reduce the strain transferred from the pillar 38 to the back-end-of-line stack 25 of the photonic chip 12 and thereby reduce or eliminate the incidence of chip-package interaction failures in adjacent portions of the back-end-of-line stack 25. The shape of the pillar 38, which may also be dual lobed, may reduce the tensile pressure without increasing the area of the pillar 38 in contact with the bond pad 34. In particular, the tensile pressure may be reduced over the area of contact between the lobed section 40 of the pillar 38 and the bond pad 34. The rotational orientation of the pillar 38 that places the smaller lobed section 40 closer to either the nearby side surface 11 of the photonic chip 12 than the larger lobed section 42 or the nearby side surface 13 of the photonic chip 12 than the larger lobed section 42 may contribute to reducing the tensile pressure.

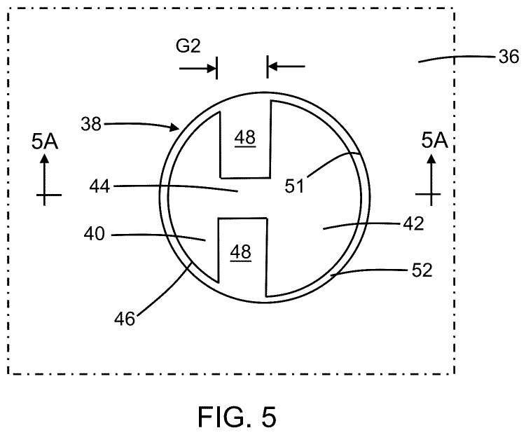

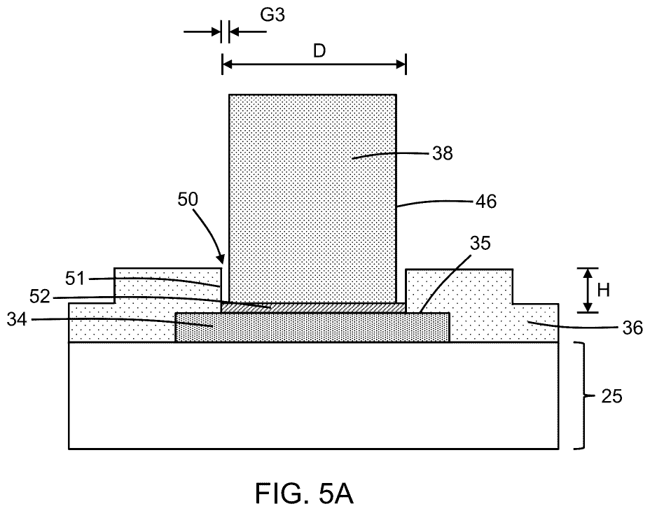

With reference to FIGS. 5, 5A and in accordance with an alternative embodiment, each electrical interconnection 18 may include a pedestal or base 52 this is positioned between the bond pad 34 and the pillar 38. In an embodiment as shown in FIG. 5, the base 52 may be a cylindrical with a round cross-sectional profile that differs from the dual-lobed shape of the pillar 38. The notches 48 in the sidewall of the pillar 38 may extend over the full height of the pillar 38 to the base 52. The opening 50 may be modified to be cylindrical with a round cross-sectional profile, instead of dual-lobed, such that the opening 50 and the base 52 have equal diameters D. The gap G3 between the outer sidewall 46 of the pillar 38 and the sidewall 51 of the opening 50 may be preserved over at least the portions of the sidewall 51 of the opening 50 adjacent to the curved portions of the lobed sections 40, 42 of the pillar 38. In an embodiment, the base 52 may fully overlap with the bond pad 34 over the entirety of the gap G3.

In an embodiment, the base 52 and the pillar 38 may be comprised of the same metal. In an embodiment, the base 52 may be comprised of a different metal from the pillar 38. In an embodiment, the base 52 may be comprised of a different metal from the bond pad 34. The presence of the base 52 filling the gap G3 may replace at least of a portion of underfill material that would otherwise fill the gap G3.

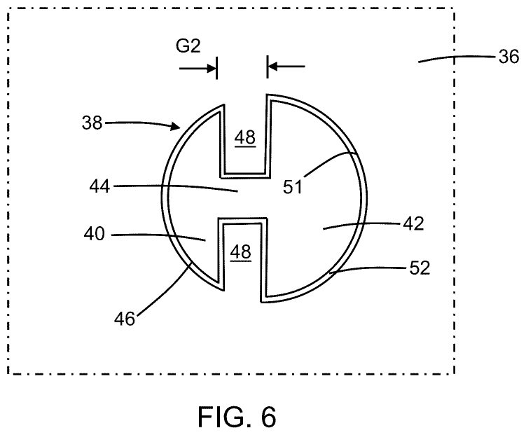

With reference to FIG. 6 and in accordance with an alternative embodiment, the base 52 may have a dual-lobed shape that mirrors the dual-lobed shape of the pillar 38, as well as the dual-lobed shape of the opening 50 in the dielectric layer 36. Specifically, the base 52 may have a lobed section that coincides in location with the lobed section 40 of the pillar 38, a lobed section that coincides in location with the lobed section 42 of the pillar 38, and a section that coincides in location with the connecting section 44 of the pillar 38.

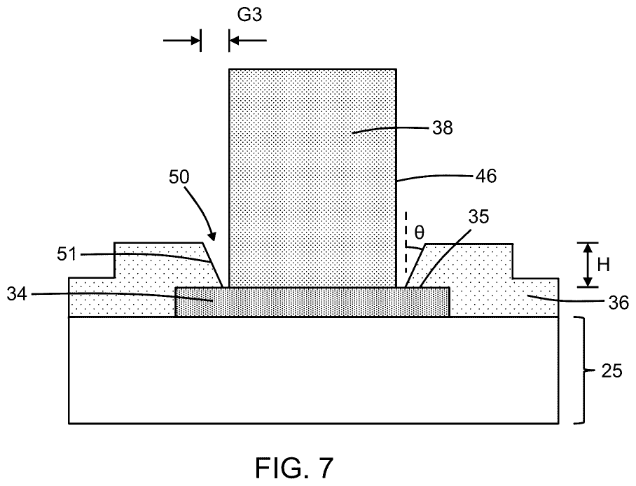

With reference to FIG. 7 and in accordance with an alternative embodiment, the sidewall 51 of the opening 50 in the dielectric layer 36 may be inclined outwardly at an acute angle that is a complementary angle to the angle θ. The angle θ may be evaluated relative to a surface normal perpendicular to a horizontal plane established by the top surface 35 of the bond pad 34. In an embodiment, the sidewall 51 of the opening 50, which is adjacent to the outer sidewall 46 of the pillar 38, may be inclined in a range of about 75° to less than 90° relative to a horizontal plane established by the top surface 35 of the bond pad 34. The width of the gap G3 may increase with increasing distance from the bond pad 34 over the height H of the opening 50.

The inclination of the sidewall 51 of the opening 50 in the dielectric layer 36, particularly with an inclination within a range of about 75° to less than 90°, may contribute to the further reduction of the strain transferred from the pillar 38 to the back-end-of-line stack 25 of the photonic chip 12. The further reduction in transferred strain may thereby further assist with reducing or eliminating the incidence of chip-package interaction failures in adjacent portions of the back-end-of-line stack 25.

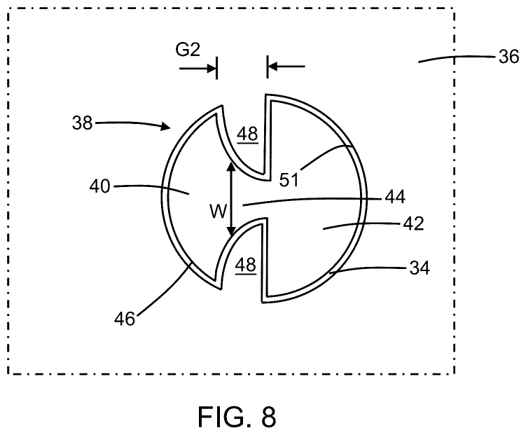

With reference to FIG. 8 and in accordance with an alternative embodiment, the connecting section 44 of the pillar 38 may connect at least a portion of the lobed section 40 of the pillar 38 to at least a portion of the lobed section 42 of the pillar 38. The connecting section 44 of the pillar 38 may be curved such that its width dimension W increases with increasing distance from the lobed section 42. The portion of the opening 50 bordering the connecting section 44 may also be curved to match the curvature of the connecting section 44 and to maintain the width dimension of the gap G3 between the sidewall 51 and the outer sidewall 46.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a photonic chip including a bond pad; and
an electrical interconnection including a pillar positioned on a portion of the bond pad, the pillar including a first lobed section, a second lobed section spaced from the first lobed section by a first gap, and a connecting section extending across a portion of the first gap to connect the first lobed section to the second lobed section.

2. The structure of claim 1 wherein the first lobed section of the pillar is smaller than the second lobed section of the pillar.

3. The structure of claim 1 further comprising:
a dielectric layer having an opening,
wherein the pillar is positioned inside the opening, the pillar has a sidewall, and the opening has a sidewall that is spaced from the sidewall of the pillar by a second gap.

4. The structure of claim 3 wherein the dielectric layer overlaps with a portion of the bond pad adjacent to the sidewall of the opening.

5. The structure of claim 3 wherein the opening has a height relative to the bond pad, and the second gap has a width dimension that is constant over the height of the opening.

6. The structure of claim 3 wherein the second gap has an average width dimension that is less than about 1 micrometer.

7. The structure of claim 3 wherein the second gap has a width dimension that increases with increasing distance from the bond pad over a height of the opening.

8. The structure of claim 3 wherein the bond pad has a planar top surface, and the sidewall of the opening is inclined at an angle in a range of about 75° to less than 90° relative to the planar top surface of the bond pad.

9. The structure of claim 3 wherein the electrical interconnection includes a base positioned between the bond pad and the pillar.

10. The structure of claim 9 wherein the base is cylindrical with a round cross-sectional profile.

11. The structure of claim 9 wherein the base has a first lobed section that coincides with the first lobed section of the pillar, a second lobed section that coincides in location with the second lobed section of the pillar, and a section that coincides with the connecting section of the pillar.

12. The structure of claim 3 wherein the opening has a first lobed section that coincides with the first lobed section of the pillar, a second lobed section that coincides in location with the second lobed section of the pillar, and a section that coincides with the connecting section of the pillar.

13. The structure of claim 12 wherein the second gap has a width dimension that is constant between the opening and the pillar.

14. The structure of claim 3 wherein the dielectric layer comprises an inorganic dielectric material.

15. The structure of claim 14 wherein the dielectric layer has a thickness of about 6 micrometers.

16. The structure of claim 3 wherein the sidewall of the opening fully surrounds the sidewall of the pillar.

17. The structure of claim 1 further comprising:
a laminate substrate that is separated from the photonic chip by a second gap,
wherein the bond pad and the electrical interconnection are disposed in the second gap.

18. The structure of claim 1 wherein the photonic chip has a side surface, the first lobed section is positioned closer to the side surface of the photonic chip than the second lobed section, and the first lobed section of the pillar is smaller than the second lobed section of the pillar.

19. The structure of claim 1 wherein the first lobed section of the pillar is smaller than the second lobed section of the pillar, and the connecting section has a width dimension that increases with increasing distance from the second lobed section of the pillar.

20. A method comprising:
forming a photonic chip including a bond pad; and
forming an electrical interconnection that includes a pillar positioned on a portion of the bond pad, wherein the pillar includes a first lobed section, a second lobed section spaced from the first lobed section by a gap, and a connecting section extending across a portion of the gap to connect the first lobed section to the second lobed section.
